(19) United States
(12) Patent Application Publication
(10) Pub. No.: US 2008/0018349 A1
(43) Pub. Date: Jan. 24, 2008

(54) METHOD FOR TESTING ELECTRICAL ELEMENTS USING AN INDIRECT PHOTOELECTRIC EFFECT

(75) Inventors: Christophe Vaucher, Bandol (FR); Jean-Jacques Aubert, Sassenage (FR)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: BEAMIND, Bandol (FR)

(21) Appl. No.: 11/833,394

(22) Filed: Aug. 3, 2007

Related U.S. Application Data
(63) Continuation of application No. PCT/FR2006/000155, filed on Jan. 24, 2006.

(30) Foreign Application Priority Data
Feb. 4, 2005 (FR) 0501094

(51) Int. Cl. G01R 31/305

(52) U.S. Cl. 324/751

(57) ABSTRACT

A method for testing or measuring electric elements uses at least one electron-discharging electrode, at least one electron-collecting electrode and at least one source of a beam of particles. The method includes ejecting electrons present in the discharging electrode by use of the beam of particles and injecting into an element the electrons supplied by the discharging electrode, and ejecting electrons present in an element by means of the beam of particles and collecting by the collecting electrode the electrons ejected from the element. The ejection of electrons present in the discharging electrode includes the application to the discharging electrode of a reflected beam of particles resulting from the reflection of an incident beam of particles on at least one element.

### CROSS-REFERENCE TO RELATED APPLICATIONS

This application is a Continuation of International Application No. PCT/FR2006/000155, filed Jan. 24, 2006, which was published in the French language on Aug. 10, 2006, under International Publication No. WO 2006/082294 A1 and the disclosure of which is incorporated herein by reference.

### BACKGROUND OF THE INVENTION

The present invention relates to the contactless electrical testing of electrical conductors arranged on an insulating substrate, using the photoelectric effect.

The present invention particularly relates to the electrical testing of interconnection supports, such as printed circuits and chip carriers.

The electrical testing of interconnection supports is a major challenge in today's electronics industry and is an integral part of their manufacturing process. The two essential test sequences to be conducted to make sure that an interconnection conductor does not have any manufacturing defects are classically the continuity test and the insulation test. The continuity test involves checking that the conductor is not cut between its ends, and more precisely between the connection points that it links, generally contact pads. The aim is thus to measure the resistance of the conductor between the connection points of the conductor and to make sure that such resistance is very low (typically in the order of one ohm). The insulation test involves making sure that each conductor of the interconnection support is electrically insulated relative to the other conductors, i.e. ,that it has a high insulation resistance, typically of several Megohms, relative to each of the other conductors and relative to all of the other conductors as a whole.

With the miniaturization and the increased complexity of integrated circuits (ICs) produced in the form of silicon chips, interconnection supports are increasingly complex just like the integrated circuits they accommodate. Thus, high density interconnection supports have conductors the length and width of which are constantly being reduced, along with the surface area of their points of connection with the integrated circuits. As a result, conventional test methods, using probe cards or beds-of-nails, are proving increasingly ill-suited to such interconnection supports.

The range of so-called “high density” interconnection supports includes HDI (High Density Interconnect) printed circuits which are present in most compact electronic equipment (mobile telephones, digital cameras, MP3 players, etc.) and chip carriers which are also called “IC package substrates”, “FC-BGA”, “Flip Chips”, “Ball Grid Arrays”, etc. In reality, chip carriers are intermediate adaptor interconnection supports, “or spark gaps”, which are interposed between the integrated circuits and the printed circuits, because integrated circuits generally have a pitch (i.e., minimum distance between conductors, particularly between input/output contacts) that is much lower than the pitch of printed circuits.

Thus, on their front face, latest generation “chip carriers” have a considerable number—up to several thousand—of connection points designed to be soldered onto the input/output contacts of a silicon chip, which are very small in size and generally covered with solder microballs of a diameter of a few tens of micrometers. On their back face, they generally have points of connection with a printed circuit (such as a mother board), which are also covered with solder balls but generally of a diameter that is greater than that of the microballs on the front face, and fewer in number. The connection points on the front face and their solder microballs are generally called “C4” for “Controlled Collapsed Chip Connection” and the connection points on the back face are called “BGA” for “Ball Grid Array” due to the shape and matrix arrangement (i.e., in lines and in columns) thereof. Such “chip carriers” also have conductors linking the C4 points to the BGA points, called “C4-to-BGA” (conductors comprising “vias”, i.e., metallic channels passing straight through the substrate and sometimes through several intermediate embedded conductive layers), and conductors linking C4 points on the front face, called “C4-to-C4”, which only interconnect contacts of the integrated circuit two by two without any link with the back face and consequently without any connection to the external environment. The “C4-to-C4” conductors are particularly difficult to test, because they are inaccessible from the back face of the chip carrier and have a small pitch of a few tens of micrometers.

Thus, a test method adapted to the testing of such interconnection supports must meet the following requirements:
(i) enable all of the connection points of the conductors to be accessed, including C4-to-C4 or C4-to-BGA type conductors, given that the distances between the connection points are short and in the order of a few tens of micrometers (distance between C4-type points) to a few hundred micrometers (distance between BGA-type points);
(ii) enable insulation and continuity tests to be conducted, and generally speaking tests or measurements to be conducted on resistive, capacitive or inductive type elements;
(iii) be rapid and enable several hundred to several thousand elements to be tested per second;
(iv) not be destructive in relation to the connection points, particularly the C4-type points (as solder microballs are fragile and generally deposited prior to the test phase); and
(v) be inexpensive to implement.

Now, the testing of chip carriers with conventional testing methods comes up against various technical problems. Firstly, the technological pitch of the probe cards (which are themselves printed circuits equipped with test probes), and/or the beds-of-nails, is too high compared to the fineness of the pitch of the C4-type connection points and their density (number of connection points per unit of surface area). Secondly, C4-type solder balls are fragile and likely to be damaged by any physical contact with probes.

To overcome these disadvantages, contactless test methods have been developed in recent years in which the photoelectric effect is used to act on the electric potential of the conductors to be tested. The photoelectric effect is created by applying to a conductive material a beam of particles having sufficient energy to communicate energy to the electrons of the conduction layer of the target material that is at least equal to their work function. The electrons are then extracted/ejected from the conductive material with determined kinetic energy, which can be almost zero, and are then speeded up by an intense electric field (several millions of Volts per meter). It shall be noted that to simplify the language, the term “photoelectric effect” is here generic and refers to a phenomenon of extracting or ejecting electrons from a target material. Indeed, with materials such as copper, gold, or conductors plated with lead-tin, sources of coherent light with a short wavelength are generally used, particularly sources of ultraviolet laser light, but sources of non-coherent light are also used as well as particles other than photons, such as a beam of ions or a beam of electrons for example.

Historically, as illustrated for example by U.S. Pat. Nos. 6,369,590 and 6,369,591, the photoelectric effect has been exclusively used to eject electrons from a conductor to be tested. As it is generally not desired—or possible—to access the conductor to apply a negative electric potential to it that would create a repulsive electric field at the moment the electrons are ejected (the conductor is generally at a floating potential), a collecting electrode taken to a positive potential enables this problem to be solved by generating a powerful electric field which attracts the electrons ejected by the conductor. The collecting electrode further enables the quantity of electricity extracted from the conductor to be collected and counted in order to deduce for example its initial electric potential therefrom. When the process of ejecting electrons in the presence of the collecting electrode is finished, the electric potential of the conductor is the same as that of the collecting electrode (when the conductor is at a floating potential).

International PCT Patent Application Publication No. WO 01/38892 provides a major improvement to test methods based on the photoelectric effect, by providing for an injection of electrons into a conductor in addition to an extraction of electrons. Electrons are injected by means of a discharging electrode (electron-emitting electrode) taken to an electric potential that is lower than that of the conductor to be tested, disposed opposite the latter and bombarded by a beam of particles.

For a better understanding, FIG. 1A shows the method of injecting electrons into a conductor as described in the international application. The target conductor 1 is arranged on a dielectric substrate 2 and has a contact pad 3 (connection point) here covered with a solder coat. A discharging electrode 6 integral with a support plate 5 in silica is disposed at a distance d from the conductor, opposite the pad 3 (here delimited by a resist area made in a protection varnish 4). The discharging electrode 6 receives a negative electric potential Vn lower than a floating potential Vf of the conductor, and its back face is bombarded by a beam BI of ultraviolet light, through the plate 5 and in the presence of a rough vacuum. Electrons (e) are ejected by the front face of the discharging electrode 6 and are projected onto the conductor 1 under the effect of a repulsive electric field E=(Vn−Vf)/d generated by the negative potential of the discharging electrode.

FIG. 1B shows a method of ejecting electrons present in the conductor I as described in the international application. A collecting electrode 7, fixed onto the support plate 5, is disposed at a distance d′ from the contact pad 3 of the conductor I and is taken to a positive electric potential Vp greater than the floating potential Vf of the conductor. The beam BI of ultraviolet light is applied to the pad 3 and electrons (e) extracted from the conductor 1 are “sucked” by the collecting electrode 7 under the effect of an attractive electric field E′=(Vp−Vf)/d′ generated by the positive electric potential Vp of the electrode 7.

However, this method has the disadvantage that the discharging electrodes 6 must be very thin, due to the fact that the beam of light is applied to their back face while electrons are ejected from their front face. This thickness is in the order of 100 to 150 Angstroms, which is barely greater than the skin thickness (50 to 100 Å) of the metal used given that, as part of the photoelectric effect, the photons penetrate the metal to a depth of approximately 50 to 100 Angstroms. It follows that the discharging electrodes are fragile, prone to oxidation and various other phenomena likely to cause them to slowly deteriorate over time.

### BRIEF SUMMARY OF THE INVENTION

Thus, embodiments the present invention are directed to a method for injecting electrons supplied by a discharging electrode into a conductor, which does not require applying a beam of particles generating a photoelectric effect to the back face of the discharging electrode.

Embodiments of the present invention are also directed to a method for taking to a target electric potential an electrical conductor arranged on an electrically insulating substrate and being at an initial electric potential higher than the target electric potential.

Embodiments of the present invention are also directed to a method for testing or measuring electric elements playing a part in the manufacture of electronic circuits, particularly for testing or measuring conductors, electrical components, electronic components or terminals of electrical or electronic components.

Embodiments to the present invention are based on a surprising observation made by taking a collecting electrode to a negative voltage while a target conductor, which is initially at a zero floating potential (ground), is bombarded by a beam of ultraviolet light. Initially, the aim of such an experiment was to check that the electric potential of the conductor did not change after the “blast”, since the electrons extracted from the conductor were supposed to inject themselves back into the conductor due to the repulsive electric field generated by the negative voltage of the collecting electrode. Now, at the end of the experiment, the conductor was at the same negative potential as the collecting electrode, which indicated that the conductor had not lost any electrons and that, on the contrary, it had received a significant quantity of electrons. It was thus deduced that a part of the beam of light had been reflected by the conductor and sent back to the collecting electrode, which then found itself subjected to the photoelectric effect under the effect of the reflected beam, and formed a discharging electrode.

After a more in-depth study of the technical effect thus discovered, embodiments of the present invention are based on the observation that the metals or materials classically used to form interconnection conductors or to cover such conductors, particularly copper, gold, soft solder with or without lead, and the solder balls of C4- or BGA-type, have a good reflection coefficient in relation to the beams of particles used to cause the “photoelectric” effect, particularly the beams of ultraviolet light. Thus, embodiments of the present invention extract electrons present in a discharging electrode by means of a reflected beam of particles resulting from an incident beam applied to a target conductor and reflecting thereon. As the discharging electrode is struck by the beam from its front face (by convention the front face is the one located opposite the target conductor) instead of being struck on its back face, the constraint imposed by previous practices, of providing a very thin discharging electrode, becomes unfounded.

Thus, one embodiment the present invention provides a method for taking to a targeted electric potential an electrical conductor that is at an initial floating electric potential higher than the targeted electric potential. The method includes disposing proximate to the conductor at least one electron-discharging electrode, taking the discharging electrode to the targeted electric potential, and ejecting electrons from the discharging electrode by use of a beam of particles and injecting the electrons supplied by the discharging electrode into the conductor. The ejection of electrons from the discharging electrode includes the application to the discharging electrode of a reflected beam of particles resulting from the reflection on the conductor of an incident beam of particles.

According to one embodiment, the initial floating electric potential of the conductor is a ground potential or a positive potential relative to the ground potential, and the targeted electric potential is a negative potential relative to the ground potential.

According to one embodiment, the method comprises a preliminary step of taking the conductor to the initial electric potential.

According to one embodiment, the conductor is taken to the initial potential by taking the electrode to the initial electric potential and by applying the beam of particles to the conductor so that electrons are ejected from the conductor and reach the electrode by causing the electric potential of the conductor to tend to the electric potential of the electrode, the latter then forming an electron-collecting electrode.

According to one embodiment, the intensity of the reflected beam of particles is between about 30% and 85% of the intensity of the incident beam of particles that strikes the conductor.

According to one embodiment, the discharging electrode has a surface treatment so as to maximize the ejection of electrons under the effect of the reflected beam of particles.

According to one embodiment, the beam of particles is a beam of ultraviolet light.

According to one embodiment, the electrons ejected and the reflected beam of particles are channelled by an orifice made in an electrically insulating separator plate disposed between the discharging electrode and the conductor.

According to one embodiment, the electrical conductor is a conductor path, a contact pad or a terminal of an electronic component.

One embodiment of the present invention relates to a method for testing or measuring electric elements by means of at least one electron-discharging electrode, at least one electron-collecting electrode and at least one source of a beam of particles, comprising ejecting electrons present in the discharging electrode by use of the beam of particles and injecting into an element the electrons supplied by the discharging electrode, ejecting electrons present in an element by use of the beam of particles and collecting the electrons ejected from the element by the collecting electrode. The ejection of electrons present in the discharging electrode includes the application to the discharging electrode of a reflected beam of particles resulting from the reflection of an incident beam of particles on at least one element.

According to one embodiment, the discharging electrode and the collecting electrode are of a same structure, the discharging electrode being capable of forming a collecting electrode or vice-versa.

According to one embodiment aiming to test the electrical insulation between two elements, the method comprises taking a first element to a first electric potential by ejecting electrons present in the first element, taking a second element to a second electric potential lower than the first electric potential by injecting electrons into the second element, and measuring the electric potential of at least one of the elements, after a lapse of time.

According to one embodiment aiming to test or measure a resistance, a capacitance or a self-inductance, the method comprises pulling a first element to a first electric potential by ejecting electrons from the first element, pulling a second element to a second electric potential lower than the first electric potential by injecting electrons into the second element, and measuring an electric charge flowing between the first and the second elements.

According to one embodiment, the method comprises the use of an electron-discharging and collecting plate comprising a plurality of electrodes, each being capable of forming a discharging electrode for discharging electrons into an element or a collecting electrode for collecting electrons ejected from an element. The electron-discharging and collecting plate comprising spaces between the electrodes enabling one part of the beam of particles to pass through the electron-discharging and collecting plate and to reach elements.

According to one embodiment, each electrode is individually accessible for an electric potential to be applied to the electrode.

According to one embodiment, the electrodes have a surface treatment so as to maximize the ejection of electrons present in the electrodes under the effect of the reflected beam of particles.

According to one embodiment, each electrode comprises a gate of thin conductors.

According to one embodiment, each electrode comprises a block of a conductive material.

According to one embodiment, the electron-discharging and collecting plate comprises electrodes disposed as a matrix, in lines and in columns.

According to one embodiment, the electron-discharging and collecting plate comprises electrodes parallel with one another.

According to one embodiment, the electron-discharging and collecting plate comprises electrodes in the form of rectilinear strips.

According to one embodiment, the method comprises the use of an electrically insulating separator plate between the electron-discharging and collecting plate and elements. The separator plate comprising orifices at locations corresponding to points of injection or collection of electrons, and forming corridors for the flow of electrons and for channeling the beam of particles.

According to one embodiment, the beam of particles is a beam of ultraviolet light.

According to one embodiment, an electric element is at least one of the following elements: an electrical conductor, an electrical component, an electronic component, a terminal of an electrical conductor and a terminal of an electrical or electronic component.

Another embodiment of the present invention relates to a method for manufacturing an interconnection support or an electronic circuit arranged on an interconnection support. The interconnection support or the electronic circuit includes electric elements. The method includes a step of testing or measuring at least one of the electric elements of the interconnection support or of the electronic circuit by use of at least one electron-discharging electrode, at least one electron-collecting electrode and at least one source of a beam of particles. The step of testing or measuring at least one of the electric elements comprises ejecting electrons present in the discharging electrode by use of the beam of particles and injecting into an element the electrons supplied by the discharging electrode, ejecting electrons present in an element by use of the beam of particles and collecting the electrons ejected from the element by the collecting electrode. The ejection of electrons present in the discharging electrode includes the application to the discharging electrode of a reflected beam of particles resulting from the reflection of an incident beam of particles on at least one element. Another embodiment of the present invention relates to a device for testing or measuring electric elements, comprising at least one source of a beam of particles, at least one electron-discharging and collecting plate comprising a plurality of electrodes that can be individually taken to an electric potential, and a control and measuring unit for controlling the beam of particles and the electric potentials applied to the electrodes and for measuring electric charges flowing through the electrodes. The device is arranged for ejecting electrons present in electrodes by use of the beam of particles and injecting the electrons supplied by the electrodes into elements, and ejecting electrons present in elements by use of the beam of particles and collecting the electrons ejected from the elements in electrodes. The device is arranged for ejecting electrons present in electrodes by applying to the electrodes a reflected beam of particles resulting from the reflection of an incident beam of particles on at least one element.

According to one embodiment, the device is arranged for conducting a test sequence for testing the electrical insulation between two elements by performing the following operations: taking a first element to a first electric potential by ejecting electrons present in the first element, taking a second element to a second electric potential lower than the first electric potential by injecting electrons into the second element, and measuring the electric potential of at least one of the elements, after a lapse of time.

According to one embodiment, the device is arranged for conducting a test or measuring sequence for testing or measuring a resistance, a capacitance or a self-inductance by performing the following operations: pulling an element to a first electric potential by ejecting electrons from the first element, pulling a second element to a second electric potential lower than the first electric potential, by injecting electrons into the second element, and measuring an electric charge flowing between the first and the second element.

According to one embodiment, the electron-discharging and collecting plate comprises a plurality of electrodes of a same structure, each being capable of forming a discharging electrode for discharging electrons into an element or a collecting electrode for collecting electrons ejected from an element, and comprises spaces between the electrodes enabling one part of the beam of particles to pass through the electron-discharging and collecting plate and to reach elements.

According to one embodiment, the electrodes of the electron-discharging and collecting plate have a surface treatment so as to maximize the ejection of electrons present in the electrodes under the effect of the reflected beam of particles.

According to one embodiment, the electron-discharging and collecting plate comprises electrodes comprising a gate of thin conductors.

According to one embodiment, the electron-discharging and collecting plate comprises electrodes comprising a block of an electrically conductive material.

According to one embodiment, the electron-discharging and collecting plate comprises the electrodes disposed as a matrix, in lines and in columns.

According to one embodiment, the electron-discharging and collecting plate comprises electrodes parallel with one another.

According to one embodiment, the electron-discharging and collecting plate comprises electrodes in the form of rectilinear strips.

According to one embodiment, the device comprises an electrically insulating separator plate disposed or to be disposed between the electron-discharging and collecting plate and the elements, the separator plate comprising orifices at locations corresponding to points of injection or collection of electrons, and forming corridors for the flow of electrons and for channeling the beam of particles.

According to one embodiment, the device comprises at least one source of a beam of ultraviolet light.

According to one embodiment, an electric element is at least one of the following elements: an electrical conductor, an electrical component, an electronic component, a terminal of an electrical conductor or a terminal of an electrical or electronic component.

### BRIEF DESCRIPTION OF THE SEVERAL VIEWS OF THE DRAWINGS

The foregoing summary, as well as the following detailed description of embodiments of the invention, will be better understood when read in conjunction with the appended drawings. For the purpose of illustrating the embodiments of the invention, there are shown in the drawings embodiments which are presently preferred. It should be understood, however, that the invention is not limited to the precise arrangements and instrumentalities shown.

In the drawings:

FIGS. 1A-1B described above respectively show a classical method of injecting electrons into a conductor and a classical method of ejecting electrons present in the conductor;

FIGS. 2A and 2B respectively show one embodiment of a method of injecting electrons into a conductor according to the invention and a method of ejecting electrons present in the conductor;

FIG. 3 shows one embodiment of a method according to the present invention for channeling an electron flux;

FIG. 4 shows the implementation of a continuity test according to one embodiment of the invention;

FIG. 5 represents a first embodiment of a discharging and collecting plate according to the present invention, and also represents in block form a control and measuring unit of a test device according to the present invention;

FIG. 6 shows an example of use of the discharging and collecting plate in FIG. 5 for the implementation of a continuity test;

FIG. 7 represents a second embodiment of a discharging and collecting plate according to the present invention; and

FIG. 8 represents a third embodiment of a discharging and collecting plate according to the present invention.

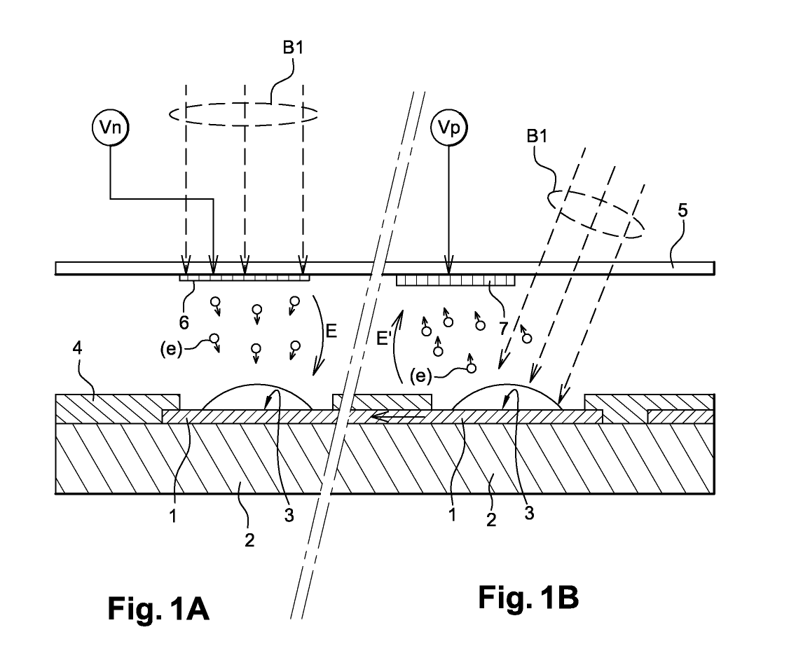

### DETAILED DESCRIPTION OF THE INVENTION

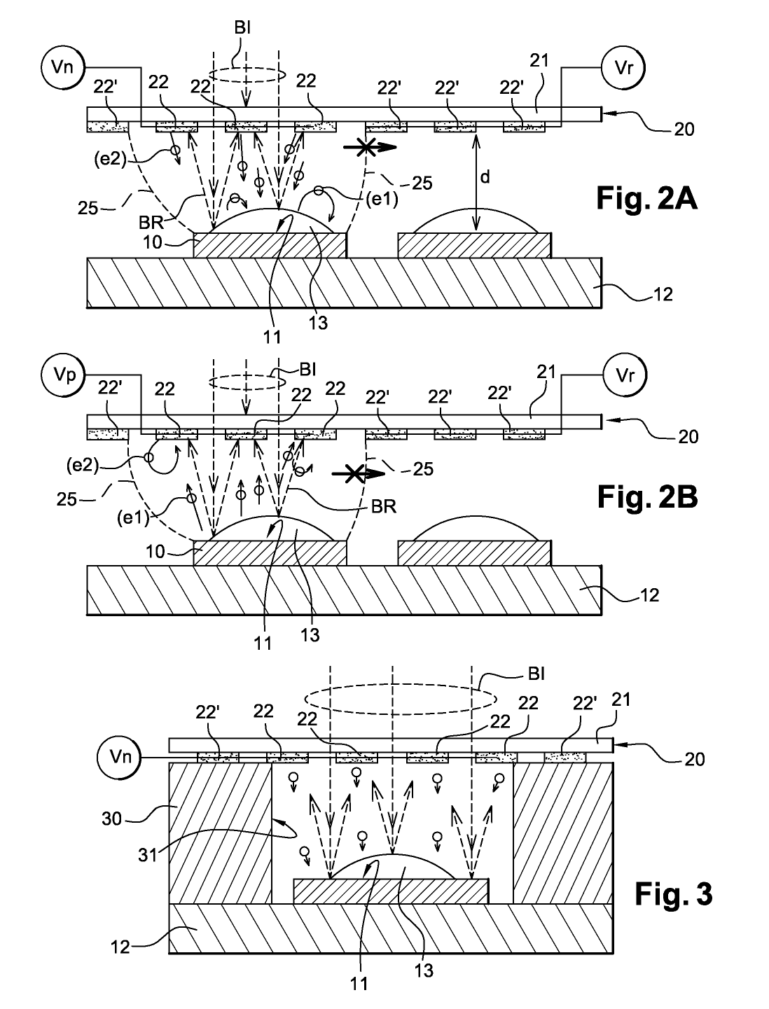

FIG. 2A is a cross-section showing one embodiment of a method according to the present invention of injecting electrons into a conductor to be tested. FIG. 2B is a cross-section showing a method of ejecting electrons present in the conductor. The second method is classical per se, but the combination thereof with the first method forms one aspect of the present invention.

The two methods are here applied to a conductor 10 arranged on an insulating substrate 12 of an interconnection support comprising various other conductors (not represented). They are implemented by use of an electron-discharging and collecting plate 20 and a beam of particles BI generating a photoelectric effect, here a beam of ultraviolet light, in the presence of a rough vacuum (partial vacuum). The photoelectric impact area, or test point, is here a contact pad 11 of the conductor 10 covered with a solder coat 13.

The discharging and collecting plate 20 comprises a silica support plate 21 that is transparent or partially transparent to the ultraviolet rays, the front face (conductor 11 side) of which comprises a plurality of electrodes 22, 22′. The electrodes 22, 22′ are individually accessible for an electric potential to be applied to each electrode. The incident beam of light BI is applied to the back face of the support plate 21, according to an angle of incidence which is here perpendicular to the support plate 21, and passes through the support plate 21 to reach the photoelectric impact area. The support plate 21 is kept parallel to the substrate 12, so that the conductor 10 is at a distance d from the electrodes 22, 22′ according to an axis perpendicular to the plane of the substrate.

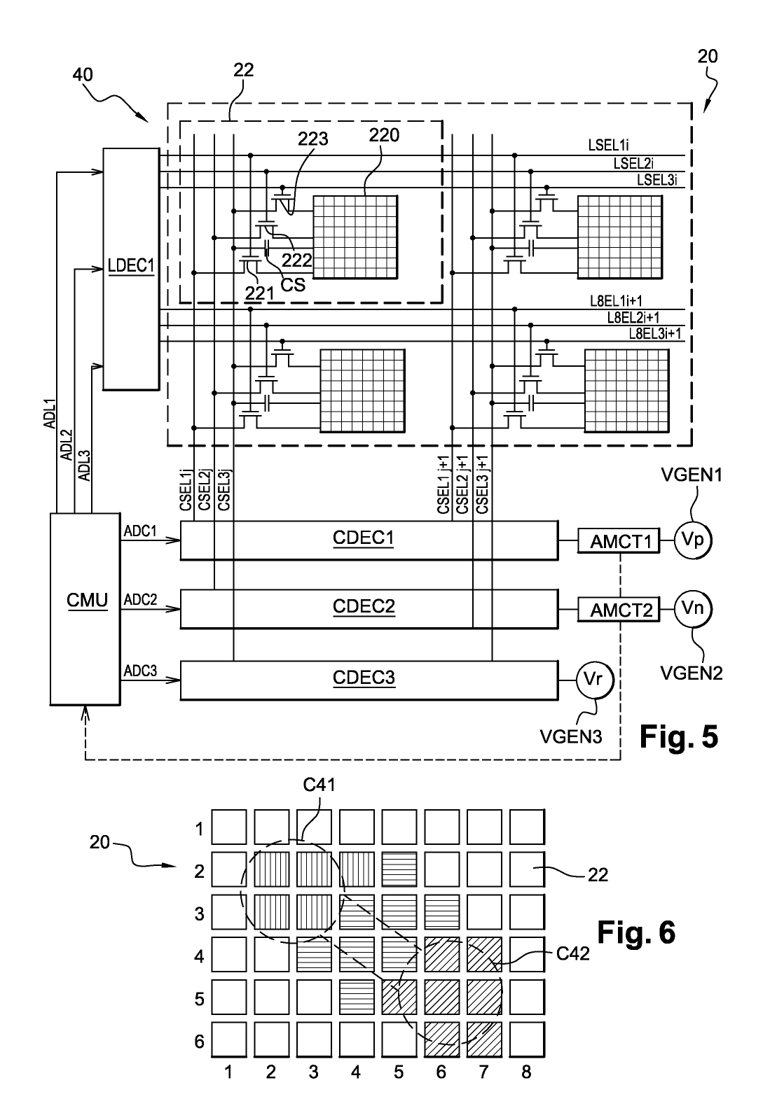

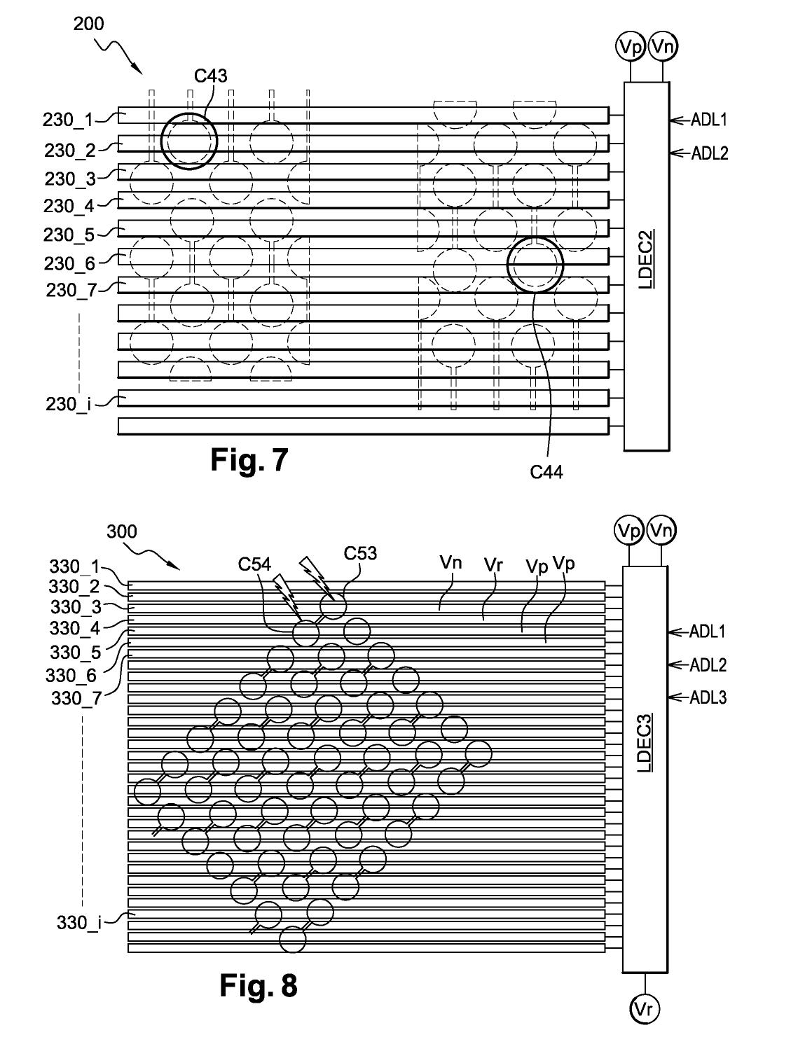

The electrodes 22, 22′ are here of a same structure and a same thickness, each one being formed by a thin coat of metal of a thickness in the order of a few hundred nanometres, deposited on the support plate 21. As it will be described below, the electrodes 22, 22′ can be square in shape (FIGS. 5 and 6) and disposed as a matrix (in lines and in columns) or form parallel strips (FIG. 7). The size of the electrodes and the spacing thereof are chosen so that the incident beam BI partially passes through the discharging and collecting plate 20 and reaches the target area. For example, an arrangement of the electrodes 22, 22′ considered to be satisfactory is such that approximately 30% to 60% of the incident beam BI reaches the impact area, the rest of the beam BI being reflected or absorbed by the back face of the electrodes 22, 22′. For this purpose, the electrodes 22, 22′ are here narrower than the contact pad 11, such that several electrodes are in the immediate vicinity of the photoelectric impact area (electrodes referenced 22) while others are outside the impact area (electrodes referenced 22′).

In FIG. 2A, the electrodes 22 are taken to an electric potential Vn lower than the electric potential Vf of the conductor 10, which is a floating potential. If necessary, the potential Vf can be previously initialized to a value known to be higher than Vn. The conductor 10 can for example be grounded or be taken to a positive potential by various known means (carbon brush, ionic bombardment) or even by means of the method represented in FIG. 2B and described below. Thus, the electric potential Vn is imposed by a negative or zero voltage (ground potential) if the floating potential Vf is a positive potential.

In accordance with the observations on which the present invention is based, the incident beam of light BI reflects on the pad 11 of the conductor 10 to form a reflected beam of light BR that is sent back onto the electrodes 22. The reflected beam of light BR comprises approximately 30 to 85% of the intensity of the incident beam of light BI, depending on the material forming or covering the target areas, materials such as gold having the highest reflection coefficients observed.

A double photoelectric effect can thus be observed:

1) the first photoelectric effect, or “direct photoelectric effect”, is produced by the impact of the incident beam BI on the pad 11 of the conductor 10 and leads to the ejection of electrons of type “e1” which are sent back into the conductor 10 due to the repulsive electric field E=(Vn−Vf)/d that reigns between the electrodes 22 and the conductor 10; and

2) the second photoelectric effect, or “indirect photoelectric effect”, is produced by the impact of the reflected beam BR on the electrodes 22 and leads to the ejection of electrons of type “e2” which are projected onto the conductor 10 by the repulsive electric field and are absorbed by the latter.

Thus, the conductor 10 charges negatively (charge of its stray capacitance) and its electric potential tends to that of the electrodes 22. At the end of the process, the conductor 10 is at the potential Vn. The duration of the process is typically in the order of a few nanoseconds and determines the duration of a photoelectric blast.

In FIG. 2B, the electrodes 22 opposite the pad 11 of the conductor 10 are taken to an electric potential Vp that is higher than the electric potential Vf of the conductor 10. If necessary, the potential Vf is initialized to a value lower than Vp, such as the ground potential or even the potential Vn obtained by use of the method of injecting electrons described above for example. As above, one part of the intensity of the incident beam of light BI reflects on the pad 11 of the conductor 10 to form a reflected beam of light BR that is sent back onto the electrodes 22. A direct photoelectric effect and an indirect photoelectric effect are once again observed but here the direct photoelectric effect is predominant while the action of the indirect photoelectric effect is canceled out by the attractive electric field E′=(Vd−Vf)/d that reigns between the electrodes 22 and the conductor 10. Thus, the impact of the incident beam BI on the pad 11 of the conductor 10 causes the ejection of electrons of type “e1” that are “sucked” by the electrodes 22 due to the attractive electric field, while the impact on the electrodes 22 of the reflected beam of light BR leads to the ejection of electrons of type “e2” that are sent back into the electrodes 22 by the attractive electric field. Thus, the conductor 10 loses electrons and its electric potential tends to the positive potential Vp of the electrodes 22. At the end of the process, which is of a same duration as the one enabling the conductor to be taken to the potential Vn if the efficiencies of the two methods have been balanced, the conductor is at the potential Vp.

It results from the above that electrode 22 can indifferently forms a discharging electrode (FIG. 2A) or a collecting electrode (FIG. 2B) according to the difference in potential imposed between the electrode and the conductor to be tested. Thus, the combination of the two methods enables a homogeneous discharging and collecting plate to be produced comprising only electrodes of a same structure, which is a major industrial advantage.

The method of injecting electrons can however be implemented alone, to test C4-to-BGA type conductors for example, by disposing the BGA-type test points on a bed-of-nails linked to a reference potential and by injecting electrons onto the C4-type test points.

It may be desired for the respective efficiencies of the method of injecting electrons and of the method of ejecting electrons to be balanced. The point of balancing the efficiencies is to obtain the same ability to adjust the electric potential of a conductor in a lapse of time corresponding to the duration of a blast, be it an adjustment by injecting or by ejecting electrons. For a better understanding, it will be assumed that the incident beam of light BI reaching the conductor 10 has 50% of the intensity of the initial beam of light applied to the support plate 21 due to the losses by reflection on conductive areas of the collector, particularly the back face of the electrodes and various connectivity elements of the electrodes described below. It will also be assumed that the target conductor and the electrodes have similar reflection coefficients in the order of 0.5. In these conditions, the direct photoelectric effect brings into play 25% of the energy of the initial beam of light while the indirect photoelectric effect brings into play 12.5% of the energy of the initial beam of light.

The efficiencies can be balanced by applying a surface treatment to the electrodes 22, such as an electrically conductive antireflection coating for example. This may be a pile-up of metal or semi-conductive coats performing an antireflection function, even imperfect. Instead of increasing the absorption of the ultraviolet beam with a surface antireflection coating or absorbent, it is also possible to maximize the ejection of electrons by providing a layer of coating having a low work function of its electrons, or even by rendering the surface of the electrodes rough, to increase their interface (boundary surface) with the external environment. Yet another solution is to increase the energy of the incident beam when implementing the method of injecting electrons by indirect photoelectric effect, in other words to modulate the energy of the beam of particles or light depending on whether electrons are being ejected or injected into a conductor.

Those skilled in the art will note that the various phenomena playing a part in the technical effect obtained are presented here in a simplified manner. The study of these phenomena and their mathematical modeling, to obtain parameters that would optimize the implementation of embodiments of the present invention to obtain similar efficiencies between the direct photoelectric effect and the indirect photoelectric effect, particularly use the solid angle notion. More particularly, if “I1” is the reflection index of the conductor 10 the potential of which is to be imposed, and I2 the reflection index of the electrodes 22, and “AS” the mean solid angle from which the electrodes 22 are seen from the conductive pad 11, obtaining similar efficiencies means that:
(1−I1)=I1*(1−I2)*AS

As a numerical example, if I1=I2=0.5, then AS must be equal to 2, given that a solid angle corresponding to a full sphere is 4 π. However, it is outside the scope of the present application to further develop the theoretical aspects of the present invention, which are within the understanding of those skilled in the art per se, in the light of the information disclosed here.

Furthermore, the rays of light forming the reflected beam of light BR are represented in FIG. 2A (and in FIGS. 2B and 3 described below) in the form of arrows in dotted lines having an orientation that may appear arbitrary considering the represented shape of the impact area of the incident beam BI and applying the laws of geometric optics. These arrows show the multidirectional nature of the orientation of the reflected beam of light BR, which covers a solid angle encompassing the electrodes 22, and show that embodiments of the invention can be implemented with any type of photoelectric target, particularly pads in gold or copper, tin-plated pads, pads bearing C4-type solder microballs or BGA-type solder balls.

It may be desirable to optimize the implementation of embodiments of the present invention by forming a corridor for the flow of the electrons to avoid those reaching neighboring conductors. According to a solution described in application publication WO 01/38892, the electrodes 22′ located in the vicinity of the useful electrodes 22 may be taken to a very repulsive electric potential Vr, such as −10V for example if the potentials Vn and Vp are respectively in the order of 0 to −5 V and in the order of 0 to +5V. As shown by dotted lines 25 in FIGS. 2A and 2B, a corridor for the flow of the electrons is thus formed, and delimited by a very repulsive electric field which surrounds the photoelectric impact and electron flow area.

According to an alternative solution shown in FIG. 3, which is simple and inexpensive, a separator plate 30 is disposed between the substrate 12 and the discharging and collecting plate 20. Such a separator plate 30 is in an electrically insulating material, such as epoxy for example, and has orifices 31 at locations corresponding to the test points of the interconnection support, i.e. the points of injection or of ejection of the electrons. Such a separator plate has various advantages:
(i) it prevents the electrons ejected from the pad 11 or from the electrodes 22 from reaching the neighboring conductors or from reaching the neighboring electrodes 22′, and as such it replaces the very repulsive electric field described above;
(ii) it prevents the rays of light reflected on the pad 11 from reaching electrodes 22′ that must not play a part in the direct or indirect photoelectric effect, which is an additional advantage compared to using a repulsive electric field, although the spurious reflections are not however a prohibitive problem;
(iii) it allows the distance d between the electrodes 22, 22′ and the target areas to be adjusted with precision; and
(iv) as it is no longer necessary to provide a very repulsive electric field to channel the electrons, it enables a test machine to be produced that only uses the two primary voltages Vn and Vp to conduct conductor insulation or continuity tests, the repulsive voltage Vr no longer being required.

The result is a simplification of the structure of the discharging and collecting plate which thus only comprises conductors supplying the two primary voltages Vn, Vp to the discharging and collecting electrodes, as it will be seen below.

A sequence of testing the insulation of the conductor 10 is performed in a classical manner per se but by using here the direct photoelectric effect and/or the indirect photoelectric effect. As a simplified example, it will be considered that the insulation of the conductor 10 must be tested relative to a second conductor 10′ (not represented). The insulation test sequence is for example conducted as follows:
1) first of all, the conductor 10 is taken to a reference potential, such as the ground for example, in a conventional manner (with a carbon brush for example) or by using the indirect or direct photoelectric effect. In this case, the electrodes 22 are taken to the ground potential and a blast of ultraviolet light is triggered. The direction of flow of the electrons to take the conductor 10 to the ground potential depends on its initial potential. In other words, it is not necessary to find out whether the result obtained is caused by the direct or indirect photoelectric effect.
2) the conductor 10 is then taken to the potential Vp by applying the voltage Vp to the electrodes 22 and by applying a blast of ultraviolet light to the conductor 10.
3) the second conductor 10′ is taken to the ground, for example in the same way as the conductor 10, and is then left floating.
4) after a lapse of time, ultraviolet light is blasted at the conductor 10′, by applying the voltage Vp to the electrodes 22.

The electrons flowing between the electrodes 22 and the conductor 10′ during step 4) are counted to determine the quantity of electricity exchanged Q. If the quantity of electricity measured Q corresponds to a reference quantity of electricity Qr determined during a calibration step, it is deduced that the conductor 10′ was still at the ground potential at the moment of the blast, such that its insulation in relation to the conductor 10 is guaranteed (and reciprocally). If the quantity of electricity Q is zero, that means that the electric potential of the conductor 10′ has gone from the voltage 0 to the voltage Vp during the abovementioned lapse of time, due to a major insulation defect. If the quantity of electricity Q is not zero but lower than Qr, it is deduced that the electric potential of the conductor 10′ has gone from the ground to a voltage situated between the ground and the voltage Vp during the abovementioned lapse of time, and that its insulation in relation to the conductor 10 is not perfect. More particularly, as part of an “on/off”-type insulation test, the conductor is then considered to be faulty (in this case the entire interconnection support is rejected). As part of a quantitative insulation test or a resistance measurement, the quantity measured Q and the duration of the lapse of time make it possible to determine the insulation resistance between the conductors 10, 10′ by referring to abacuses, and to decide whether this is higher or lower than a threshold for rejecting the interconnection support.

As in practice the insulation is tested between each conductor and all of the other conductors of a interconnection support. This method of testing insulation between two conductors is designed to be applied by iteration to all of the pairs of conductors to be tested on a medium. However, to avoid testing each pair of conductors, the insulation of a conductor in relation to a group of conductors can be tested globally and in an iterative manner. For example, all of the conductors are initialized to the ground and a first conductor is taken to the voltage Vp and is tested in relation to the others. If its voltage remains equal to Vp, the conductor is properly insulated. After each test of a conductor in relation to the group of the other conductors, a new conductor is taken out of the group and is taken to the voltage Vp (leaving the conductors previously tested at the voltage Vp) and so on and so forth until the initial group of conductors only comprises a single conductor and only one group of conductors remains at the voltage Vp. When a defect is detected between a conductor and a group of conductors, the global test process can be stopped to test the faulty conductor relative to each of the conductors in the group.

Moreover, various alternative embodiments of this insulation test method are possible, particularly as regards the electric potentials used. For example, a negative potential could be used instead of the ground potential.

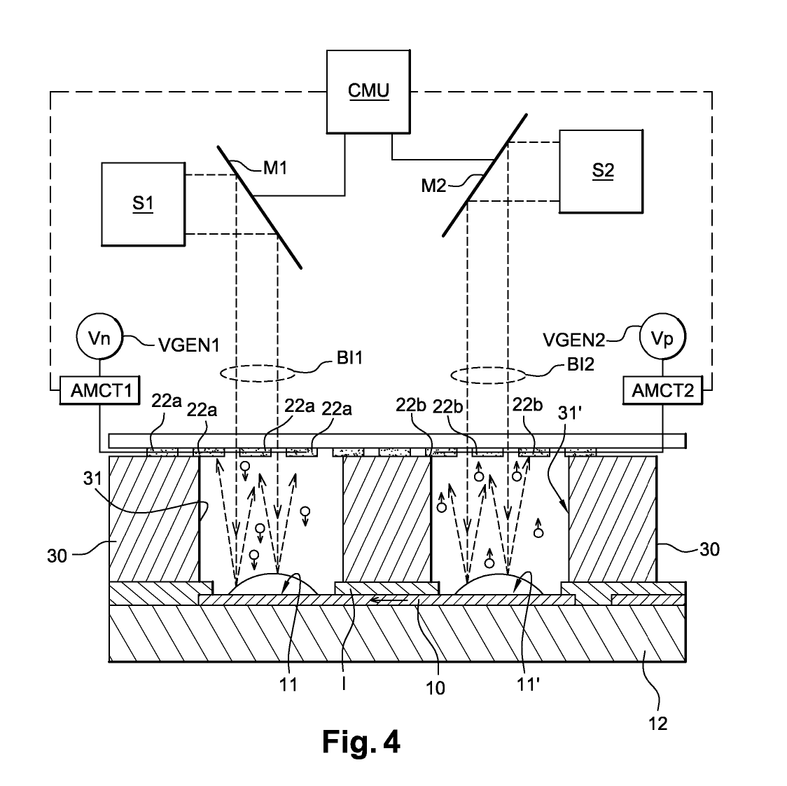

A sequence of testing the continuity of the conductor 10 is shown in FIG. 4. The conductor 10, represented in longitudinal section, has the contact pad 11 already described at one of its ends and has a contact pad 11′ at its other end. The electrodes opposite the pad 11 are designated 22a and those opposite the end 11′ are designated 22b. The test sequence is conducted here using the separator plate 30, which has an orifice 31 for the electrons to flow between the pad 11 and the electrodes 22a and an orifice 31′ for the electrons to flow between the pad 11′ and the electrodes 22b. The electrodes 22a are taken to the potential Vn (such as 0V for example) by a voltage source VGEN1, through an acquisition and measuring circuit AMCT1. The electrodes 22b are taken to the potential Vp (such as 5V for example) by a voltage source VGEN2, through an acquisition and measuring circuit AMCT2. The test sequence also involves two sources S1, S2 of ultraviolet light and two motorized mirrors M1, M2 the orientation of which is driven by a control and measuring unit CMU. The circuits AMCT1, AMCT2 are also linked to the unit CMU to analyze the measurement results.

The source S1 supplies an incident beam of light BI1 that is sent by the mirror M1 onto the pad 11 and the source S2 supplies an incident beam of light BI2 that is sent by the mirror M2 onto the pad 11′. Thus, the pad 11 is pulled towards the potential Vn by indirect photoelectric effect (injection of electrons) while the pad 11′ is pulled towards the potential Vp by direct photoelectric effect (ejection of electrons), and electrons flow in the conductor (schematized by a current I the direction of which is the opposite of the direction of flow of the electrons). The electric charge Q collected by the pad 11′ is preferably measured in differential mode by the circuits AMCT1, AMCT2 (respectively charge injected into the pad 11 and charge extracted from the pad 11′) so as to detect any spurious phenomena that might cause a loss and/or an injection of electric charges into the test loop. Abacuses developed during a stage of calibrating the device enable the unit CMU to deduce therefrom the value of the series resistance R of the conductor 10, which varies according to the charge collected.

Therefore, this method can be used as a resistance measuring method, independently of the conductor test, to measure resistive components for example. According to the same principle, a capacitance value “C” can be measured between two conductors by virtue of the relation existing between capacitance, electric charge “Q” and voltage applied “V” (Q=CV). Furthermore, a self-inductance value can be measured.

In addition, although the examples described here relate to testing conductors, embodiments of the present invention also apply to testing electrical components or to measuring their electrical characteristics (resistances, capacitances and self-inductances). Such components can be tested in an isolated configuration or by being fixed onto an interconnection support. The ultraviolet beam generating the photoelectric effect can be directly applied to the terminals of components to be tested or to interconnection conductive paths to which these components are linked (called “in situ” test, once the components are mounted).

Moreover, embodiments of the present invention are not limited to testing passive components and can also relate to testing or measuring active electronic components. It is a well-known fact that an active component can be modeled in the form of a set of passive components. For example, a MOS transistor can be modeled as a sum of capacitances and resistances. The injection/extraction of electrons on terminals of an active component enables the electrical characteristics of the component to be determined. The injection/extraction of electrons in passive or active components can furthermore be performed by use of a discharging and collecting plate comprising electrodes having a shape adapted to the terminals of components, particularly surface mount components (SMC).

FIG. 5 represents in block form the general architecture of one embodiment of a test device 40 according to the present invention. The device 40 comprises the discharging and collecting plate 20, the control and measuring unit CMU, such as a microcontroller for example, and various peripherals of the unit CMU, i.e.:
the sources of ultraviolet light S1, S2 described above (not represented in the Figure);
the motorized mirrors M1, M2 described above (not represented in the Figure);
the circuits AMCT1, AMCT2 described above;
the voltage sources VGEN1, VGEN2 described above;
a voltage source VGEN3 to supply the repulsive voltage Vr (when the separator plate is not used);
a line decoder LDEC1; and
three column decoders CDEC1, CDEC2, CDEC3.

The decoder CDEC1 is electrically powered by the generator VGEN1, through the circuit AMCT1. The decoder CDEC2 is electrically powered by the generator VGEN2, through the circuit AMCT2, and the decoder CDEC3 is electrically powered by the generator VGEN3.

The discharging and collecting plate 20 comprises a plurality of electrodes 22 arranged in lines and in columns, each having a line rank “i” and a column rank “j”. Only four electrodes 22 are represented on the Figure for the sake of simplicity. Each electrode 22 of rank i, j comprises:
a metal pad 220 forming the electrode as such, to send or collect electrons, here square in shape and formed by a gate of thin conductors (a one-piece coat of metal plate can also be provided);
a transistor-switch 221 the control gate of which is linked to an output of the decoder LDEC1 through a line selection line LSEL1i, the drain of which is linked to an output of the decoder CDEC1 through a column selection line CSEL1j, and the source of which is linked to the electrode 220;
a transistor-switch 222 the control gate of which is linked to an output of the decoder LDEC1 through a line selection line LSEL2i, the drain of which is linked to an output of the decoder CDEC2 through a column selection line CSEL2j, and the source of which is linked to the electrode 220;
a transistor-switch 223 the control gate of which is linked to an output of the decoder LDEC1 through a line selection line LSEL3i, the drain of which is linked to an output of the decoder CDEC3 through a column selection line CSEL3j, and the source of which is linked to the electrode 220; and
a measuring capacitance CS, linking the electrode 220 to a reference potential, here the voltage Vr supplied on the line CSEL3j by the decoder CDEC3. This capacitance CS is for example the stray capacitance of one of the transistors 221 to 223, or the resulting stray capacitance formed by the stray capacitances of each of the transistors. It forms a temporary means of storing the charges collected during a blast, and enables the circuits AMCT1, AMCT2 to measure quantities of electricity exchanged by photoelectric effect. Thus, once the blast is completed, the charge stored is emptied by grounding the conductor to which it is linked, to recover and measure the charge Q taken off during the blast, which enables, as indicated above, a series resistance value to be deduced.

To select the electrodes 22 and to apply one of the voltages Vp, Vn, Vr to the selected electrodes, the unit CMU supplies the following signals to the decoder LDEC1:
a line address signal ADL1 that designates the lines LSEL1 to be activated to switch on the transistors-switches linked to these lines;
a line address signal ADL2 that designates the lines LSEL2 to be activated to switch on the transistors-switches linked to these lines; and
a line address signal ADL3 that designates the lines LSEL3 to be activated to switch on the transistors-switches linked to these lines.

The unit CMU also supplies the following signals to the decoders CDEC1 to CDEC3:
to the decoder CDEC1, a column address signal ADC1 that designates the lines CSEL1 that must receive the voltage Vp;
to the decoder CDEC2, a column address signal ADC2 that designates the lines CSEL2 that must receive the voltage Vn; and
to the decoder CDEC3, a column address signal ADC3 that designates the lines CSEL3 that must receive the voltage Vr.

Such multiplexed addressing using the voltages Vp, Vn, Vr as column selection signals, enables the unit CMU to independently apply one of the aforementioned voltages to each of the electrodes.

For a better understanding, FIG. 6 represents by a top view an example of selecting electrodes 22 for the application of a continuity test to a C4-to-C4 type conductor. The conductor is located under the discharging and collecting plate 20 and is represented in dotted lines, by transparency. It has two end pads C41, C42 provided with solder microballs (not visible in the Figure) and forming two test points for the continuity test. The electrodes are schematically represented in the shape of squares, without taking into account the selection lines and the transistors described above (the actual spacing between the useful metal electrodes 220 thus being greater than the one shown on FIG. 6). By allocating a rank i ranging from 1 to 6 to the six lines of electrodes 22 represented (from top to bottom) and a rank j ranging from 1 to 8 to the eight columns of electrodes 22 represented (from left to right), the unit CMU applies address signals to the decoders LDEC1 and CDEC1 to CDEC3 such that:
the electrodes of rank (2,2), (2,3), (3,2), (3,3) located under the pad C41 receive the voltage Vp (vertical hatching), in order to take the pad C41 to the voltage Vp by direct photoelectric effect;
the electrodes of rank (4,6), (4,7), (5,6), (5,7), (6,6), (6,7) extending in whole or in part under the pad C41 receive the voltage Vn (transverse hatching) to take the pad C41 to the voltage Vn by indirect photoelectric effect; and
the electrodes of rank (2,5), (3,4), (3,5), (3,6), (4,3), (4,4), (4,5), (5,4) extending between the photoelectric impact areas receive the repulsive voltage Vr (horizontal hatching) to delimit the channels for the flow of the electrons.

FIG. 7 represents one embodiment of a discharging and collecting plate 200 according to the present invention in which the electrodes described above are replaced by conductive strips 230-1, 230-2, . . . 230-i parallel with one another and here rectilinear in shape, although strips in zigzag shape, in “Z” shape, in “S” shape, etc. can also be provided. The structure of the discharging and collecting plate is therefore considerably simplified. The strips 230-i are voltage- and selection-driven by a line decoder LDEC2 receiving only the voltages Vp and Vn as voltages to be multiplexed, and receiving only two address signals ADL1, ADL2 respectively designating the strips that must receive the voltage Vp and the strips that must receive the voltage Vn. The transport of the repulsive voltage Vr is thus removed, which implies using an electrically insulating separator plate.

Like the previous one, the discharging and collecting plate 200 enables insulation and continuity tests to be conducted on all types of conductors. As an example, it will be considered that an insulation test must be conducted between two conductive pads, of C4-type for example, belonging to different equipotentials (conductors), designated C43 and C44 on FIG. 7. To conduct this test, the conductive strip 230-2 passing above the pad C43 is taken to the potential Vn, while the conductive strips 230-6, 230-7 passing in whole or in part above the pad C44 are taken to the voltage Vp. A first blast of ultraviolet light is performed above the pads C43, C44 to respectively take them to the voltage Vn and to the voltage Vp. After a lapse of time, the conductive strip 230-2 is taken to the potential Vp, a blast of ultraviolet light is performed above the pad C43 and the quantity of electricity supplied by the generator VGEN1 is counted to determine, as indicated above, whether or not the pad C43 is still at the potential Vn.

As another example of an embodiment, FIG. 8 represents a discharging and collecting plate 300 also comprising conductive strips 330-1, 330-2, 330-3, 330-4, 330-5, 330-6 . . . 330-i parallel with one another and rectilinear in shape. The strips 330-i are here voltage- and selection-driven by a line decoder LDEC3 receiving the three voltages Vp, Vn, Vr and three address signals ADL1, ADL2, ADL3 respectively designating the strips that must receive the voltage Vp, the strips that must receive the voltage Vn and the strips that must receive the repulsive voltage Vr. FIG. 8 also shows an insulation test conducted between two conductive pads C53, C54 (the equipotentials linking the conductive pads here being arranged slantwise relative to the longitudinal axis of the conductive strips). The conductive strip 330-3 passing above the pad C53 is taken to the potential Vn, the conductive strip 330-4 passing partially above the pad C53 and partially above the pad C54 is taken to the repulsive potential Vr, and the conductive strips 330-5, 330-6 passing above the pad C54 are taken to the potential Vp. A first blast of ultraviolet light is performed above the pads C53, C54 to respectively take them to the voltage Vn and to the voltage Vp. After a lapse of time, the conductive strip 330-3 is taken to the potential Vp, a blast of ultraviolet light is performed above the pad C53 and the quantity of electricity is counted to determine whether or not the pad C53 is still at the potential Vn.

It will be understood by those skilled in the art that various other alternative embodiments of the present invention are possible, particularly as regards the implementation of the continuity or insulation tests, the production of the collecting and discharging plate, the production of the control, acquisition and measuring means described above, and the choice of the test voltages Vp, Vn, Vr. When the collecting and discharging electrodes are arranged as a matrix, they can have various other shapes than those described above, particularly a round or triangular shape, or any form of parallelogram. Furthermore, although an arrangement of the electrodes on a support plate parallel to the interconnection substrate is preferred for the industrial implementation of embodiments of the present invention, such an arrangement is in no way imperative to obtain the technical effect sought. The electrodes can for example comprise a cylinder portion or a tapered metal part extending towards the conductors, so as to form themselves corridors for the flow of electrons. They may also be flat as described above but oriented with a non-zero angle relative to the plane of the interconnection support. In addition, although it has been indicated above that the width (or the diameter) of the electrodes is smaller than the smallest width of a conductor to be tested, so as to create spaces enabling the incident beam of light to reach the conductor, other solutions may be considered, particularly electrodes having a larger surface area and having apertures or windows allowing the incident beam of light to pass.

It will also be understood by those skilled in the art that the various structures of embodiments of discharging and collecting plates according to the present invention, despite being initially provided for a combined implementation of the indirect photoelectric effect and the direct photoelectric effect, form independent inventions per se which each have their own advantages. Thus, these structures of discharging and collecting plates can also be used to implement test or measuring methods in which the indirect photoelectric effect is not used (or in which the direct photoelectric effect is not used), electrons being injected (or extracted) by means of a bed-of-nails for example, or any other method, particularly the methods of injecting electrons described in application publication WO 01/38892. In this case, the structures of discharging and collecting plates are used as collecting plates only (or as discharging plates only), but the advantages they offer remain the same (particularly shape and arrangement of the electrodes).

Various applications of the present invention are also possible and the present invention is not limited to testing naked interconnection supports, as explained above. Embodiments of the present invention particularly enable printed circuits equipped with components to be measured or tested, passive and active electrical and electronic components to be tested or measured, terminals of components to be tested, etc. Embodiments of the present invention also enable the so-called “in situ” test to be conducted, i.e., measuring the value of electronic components mounted onto an interconnection support (the target areas for the photoelectric effect being either the terminals of the components themselves or paths or pads linked to these terminals). It also enables conductors present in silicon integrated circuits to be tested, by performing blasts on input/output contacts linked by equipotentials, as well as conductors present on flat screens and generally speaking any conductor or component offering test points accessible from the external environment to be tested.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A method for taking to a targeted electric potential an electrical conductor that is at an initial floating electric potential higher than the targeted electric potential, the method comprising:
disposing proximate to the conductor at least one electron-discharging electrode;
taking the discharging electrode to the targeted electric potential; and
ejecting electrons from the discharging electrode by use of a beam of particles and injecting the electrons supplied by the discharging electrode into the conductor, the ejection of electrons from the discharging electrode including the application to the discharging electrode of a reflected beam of particles resulting from the reflection on the conductor of an incident beam of particles.

2. The method according to claim 1, wherein the initial floating electric potential of the conductor is a ground potential or a positive potential relative to the ground potential, and the targeted electric potential is a negative potential relative to the ground potential.

3. The method according to claim 1, comprising a preliminary step of taking the conductor to the initial electric potential.

4. The method according to claim 3, wherein the conductor is taken to the initial potential by taking the electrode to the initial electric potential and by applying the beam of particles to the conductor so that electrons are ejected from the conductor and reach the electrode by causing the electric potential of the conductor to tend to the electric potential of the electrode, the latter then forming an electron-collecting electrode.

5. The method according to claim 1, wherein the intensity of the reflected beam of particles is between about 30% and 85% of the intensity of the incident beam of particles that strikes the conductor.

6. The method according to claim 1, wherein the discharging electrode has a surface treatment so as to maximize the ejection of electrons under the effect of the reflected beam of particles.

7. The method according to claim 1, wherein the beam of particles is a beam of UV light.

8. The method according to claim 1, wherein the electrons ejected and the reflected beam of particles are channelled by an orifice made in an electrically insulating separator plate disposed between the discharging electrode and the conductor.

9. The method according to claim 1, wherein the electrical conductor is a conductor path, a contact pad or a terminal of an electronic component.

10. A method for testing or measuring electric elements by use of at least one electron-discharging electrode, at least one electron-collecting electrode and at least one source of a beam of particles, the method comprising:
ejecting electrons present in the discharging electrode by use of the beam of particles and injecting into an element the electrons supplied by the discharging electrode; and
ejecting electrons present in an element by use of the beam of particles and collecting the electrons ejected from the element by the collecting electrode, the ejection of electrons present in the discharging electrode including the application to the discharging electrode of a reflected beam of particles resulting from the reflection of an incident beam of particles on at least one element.

11. The method according to claim 10, wherein the discharging electrode and the collecting electrode are of a same structure, the discharging electrode being capable of forming a collecting electrode or vice-versa.

12. The method according to claim 10, for testing the electrical insulation between two elements, the method comprising:
taking a first element to a first electric potential by ejecting electrons present in the first element;
taking a second element to a second electric potential lower than the first electric potential by injecting electrons into the second element; and
measuring the electric potential of at least one of the elements, after a lapse of time.

13. The method according to claim 10, for testing or measuring a resistance, a capacitance or a self-inductance, further comprising:
pulling a first element to a first electric potential by ejecting electrons from the first element;
pulling a second element to a second electric potential lower than the first electric potential, by injecting electrons into the second element; and
measuring an electric charge flowing between the first and the second elements.

14. The method according to claim 10, comprising the use of an electron-discharging and collecting plate including a plurality of electrodes, each being capable of forming a discharging electrode for discharging electrons into an element or a collecting electrode for collecting electrons ejected from an element, and comprising spaces between the electrodes enabling one part of the beam of particles to pass through the electron-discharging and collecting plate and to reach elements.

15. The method according to claim 14, wherein each electrode is individually accessible for an electric potential to be applied to the electrode.

16. The method according to claim 14, wherein the electrodes have a surface treatment so as to maximize the ejection of electrons present in the electrodes under the effect of the reflected beam of particles.

17. The method according to claim 14, wherein each electrode comprises a gate of thin conductors.

18. The method according to claim 14, wherein each electrode comprises a block of a conductive material.

19. The method according to claim 14, wherein the electron-discharging and collecting plate comprises electrodes disposed as a matrix, in lines and in columns.

20. The method according to claim 14, wherein the electron-discharging and collecting plate comprises electrodes parallel with one another.

21. The method according to claim 20, wherein the electron-discharging and collecting plate comprises electrodes in the form of rectilinear strips.

22. The method according to claim 14, comprising the use of an electrically insulating separator plate between the electron-discharging and collecting plate and elements, the separator plate comprising orifices at locations corresponding to points of injection or collection of electrons, and forming corridors for the flow of electrons and for channeling the beam of particles.

23. The method according to claim 10, wherein the beam of particles is a beam of UV light.

24. The method according to claim 10, wherein an electric element is at least one of the following: an electrical conductor, an electrical component, an electronic component, a terminal of an electrical conductor and a terminal of an electrical or electronic component.

25. A method for manufacturing an interconnection support or an electronic circuit arranged on an interconnection support, the interconnection support or the electronic circuit comprising electric elements, the method comprising a step of testing or measuring at least one of the electric elements of the interconnection support or of the electronic circuit implemented by use of at least one electron-discharging electrode, at least one electron-collecting electrode and at least one source of a beam of particles , wherein the step of testing or measuring at least one of the electric elements comprises:
ejecting electrons present in the discharging electrode by use of the beam of particles and injecting into an element the electrons supplied by the discharging electrode; and
ejecting electrons present in an element by use of the beam of particles and collecting the electrons ejected from the element by the collecting electrode, including the application to the discharging electrode of a reflected beam of particles resulting from the reflection of an incident beam of particles on at least one element.

26. The method according to claim 26, wherein the discharging electrode and the collecting electrode are of a same structure, the discharging electrode being capable of forming a collecting electrode or vice-versa.

27. The method according to claim 26, wherein the step of testing or measuring at least one of the electric elements comprising comprises a step of testing the electrical insulation between two elements which comprises:
taking a first element to a first electric potential by ejecting electrons present in the first element;
taking a second element to a second electric potential lower than the first electric potential by injecting electrons into the second element; and
measuring the electric potential of at least one of the elements, after a lapse of time.

28. The method according to claim 26, wherein the step of testing or measuring at least one of the electric elements comprising comprises a step of testing or measuring a resistance, a capacitance or a self-inductance which comprises:
pulling a first element to a first electric potential by ejecting electrons from the first element;
pulling a second element to a second electric potential lower than the first electric potential, by injecting electrons into the second element; and
measuring an electric charge flowing between the first and the second elements.

29. The method according to claim 26, wherein the electron-discharging and collecting plate comprises electrodes disposed as a matrix, in lines and in columns.

30. The method according to claim 26, wherein the electron-discharging and collecting plate comprises electrodes parallel with one another.

31. The method according to claim 26, wherein the electron-discharging and collecting plate comprises electrodes in the form of rectilinear strips.

32. The method according to claim 26, wherein the beam of particles is a beam of UV light.

33. The method according to claim 26, wherein said at least one of the electric element is one of the following: an electrical conductor, an electrical component, an electronic component, a terminal of an electrical conductor and a terminal of an electrical or electronic component.

34. A device for testing or measuring electric elements, the device comprising:
at least one source of a beam of particles;
at least one electron-discharging and collecting plate comprising a plurality of electrodes that can be individually taken to an electric potential;
a control and measuring unit, for controlling the beam of particles and the electric potentials applied to the electrodes, and for measuring electric charges flowing through the electrodes,
the device being arranged for:
ejecting electrons present in electrodes by use of the beam of particles and injecting the electrons supplied by the electrodes into elements,
ejecting electrons present in elements by use of the beam of particles and collecting the electrons ejected from the elements in electrodes, and
ejecting electrons present in electrodes by applying to the electrodes a reflected beam of particles resulting from the reflection of an incident beam of particles on at least one element.

35. The device according to claim 34, arranged for conducting a test sequence for testing the electrical insulation between two elements by performing the following operations:
taking a first element to a first electric potential by ejecting electrons present in the first element,
taking a second element to a second electric potential lower than the first electric potential by injecting electrons into the second element, and
measuring the electric potential of at least one of the elements, after a lapse of time.

36. The device according to claim 34, arranged for conducting a test or measuring sequence for testing or measuring a resistance, a capacitance or a self-inductance by performing the following operations:
pulling an element to a first electric potential by ejecting electrons from the first element,
pulling a second element to a second electric potential lower than the first electric potential, by injecting electrons into the second element, and
measuring an electric charge flowing between the first and the second element.

37. The device according to claim 34, wherein the electron-discharging and collecting plate comprises a plurality of electrodes of a same structure, each being capable of forming a discharging electrode for discharging electrons into an element or a collecting electrode for collecting electrons ejected from an element, and comprises spaces between the electrodes enabling one part of the beam of particles to pass through the electron-discharging and collecting plate and to reach elements.

38. The device according to claim 34, wherein the electrodes of the electron-discharging and collecting plate have a surface treatment so as to maximize the ejection of electrons present in the electrodes under the effect of the reflected beam of particles.

39. The device according to claim 34, wherein the electron-discharging and collecting plate comprises electrodes comprising a gate of thin conductors.

40. The device according to claim 34, wherein the electron-discharging and collecting plate comprises electrodes comprising a block of an electrically conductive material.

41. The device according to claim 34, wherein the electron-discharging and collecting plate comprises the electrodes disposed as a matrix, in lines and in columns.

42. The device according to claim 34, wherein the electron-discharging and collecting plate comprises electrodes parallel with one another.

43. The device according to claim 42, wherein the electron-discharging and collecting plate comprises electrodes in the form of rectilinear strips.

44. The device according to claim 34, comprising an electrically insulating separator plate disposed or to be disposed between the electron-discharging and collecting plate and the elements, the separator plate comprising orifices at locations corresponding to points of injection or collection of electrons, and forming corridors for the flow of electrons and for channeling the beam of particles.

45. The device according to claim 34, comprising at least one source of a beam of UV light.

46. The device according to claim 34, wherein an electric element is at least one of the following elements: an electrical conductor, an electrical component, an electronic component, a terminal of an electrical conductor or a terminal of an electrical or electronic component.
